(19) United States
(12) Patent Application Publication
(10) Pub. No.: US 2025/0298184 A1
(43) Pub. Date: Sep. 25, 2025

(54) OPTICAL WAVEGUIDE STRUCTURE AND SEMICONDUCTOR OPTICAL AMPLIFIER

(71) Applicant: FURUKAWA ELECTRIC CO., LTD., Tokyo (JP)

(72) Inventors: Tatsuru KUBOTA, Tokyo (JP); Masahiro YOSHIDA, Tokyo (JP)

(73) Assignee: FURUKAWA ELECTRIC CO., LTD., Tokyo (JP)

(21) Appl. No.: 19/227,603

(22) Filed: Jun. 4, 2025

Related U.S. Application Data
(63) Continuation of application No. PCT/JP2024/003719, filed on Feb. 5, 2024.

(30) Foreign Application Priority Data
Feb. 3, 2023 (JP) 2023-015637

(51) Int. Cl. G02B 6/028; G02B 6/036; G02B 6/122

(52) U.S. Cl. CPC G02B 6/028; G02B 6/03622; G02B 6/1228

(57) ABSTRACT

An optical waveguide structure includes: a first waveguide that has a layered structure in which layering is performed in a first direction, includes a first core layer that extends in a second direction, and a first cladding layer that has an end surface in the second direction; and a second waveguide that has a layered structure in which layering is performed in the first direction, includes a second core layer that is adjacent to the first core layer in the second direction, that is optically connected to the first core layer, and that, at least in an end portion of the second waveguide in an opposite direction to the second direction, extends in the second direction, and a second cladding layer that sandwiches the second core layer in the first direction.

### CROSS-REFERENCE TO RELATED APPLICATIONS

This application is a continuation of International Application No. PCT/JP2024/003719, filed on Feb. 5, 2024 which claims the benefit of priority of the prior Japanese Patent Application No. 2023-015637, filed on Feb. 3, 2023, the entire contents of which are incorporated herein by reference.

### BACKGROUND OF THE INVENTION

### 1. Field of the Invention

The present disclosure relates to an optical waveguide structure and a semiconductor optical amplifier.

### 2. Description of the Related Art

In the related art, a semiconductor optical amplifier is known that includes an optical waveguide structure configured with a buried waveguide and a high-mesa waveguide (for example, refer to Japanese Patent Application Laid-open No. 2021-27314).

### SUMMARY OF THE INVENTION

As a result of performing diligent research, the inventors found out that, in the optical waveguide structure of the abovementioned type, when an interface having a different refractive index is generated in an end face of the cladding of the buried waveguide which is on the side of the high-mesa waveguide, there are times when the light reflected from the interface gets recoupled with the buried waveguide. When the reflected light is input to a semiconductor optical amplifier that either includes an optical waveguide structure or is optically connected to an optical waveguide structure, there is a risk of occurrence of an unfavorable phenomenon such as generation of ripples in the gain spectrum.

In that regard, it is desirable to provide an optical waveguide structure and a semiconductor optical amplifier in a new and improved manner so that, for example, it becomes possible to hold down a situation in which the reflected light, which is reflected from an interface on the cladding, gets recoupled with a waveguide.

In some embodiments, an optical waveguide structure includes: a first waveguide that has a layered structure in which layering is performed in a first direction, includes a first core layer that, at least in an end portion of the first waveguide in a second direction which intersects with the first direction, extends in the second direction, and a first cladding layer that encloses the first core layer and that has an end surface in the second direction; and a second waveguide that has a layered structure in which layering is performed in the first direction, includes a second core layer that is adjacent to the first core layer in the second direction, that is optically connected to the first core layer, and that, at least in an end portion of the second waveguide in an opposite direction to the second direction, extends in the second direction, and a second cladding layer that sandwiches the second core layer in the first direction, the optical waveguide structure transmitting a light in the second direction or in the opposite direction to the second direction, and the end surface of the first cladding layer constituting a first interface between the first cladding layer and a portion having a different refractive index from a refractive index of the first cladding layer. The first interface includes a first reflecting surface configured to reflect a part of a transmitted light toward a direction inclined with respect to either the second direction or the opposite direction to the second direction to prevent the light reflected by the first reflecting surface from recoupling into the first waveguide or the second waveguide.

In some embodiments, a semiconductor optical amplifier includes the optical waveguide structure.

The above and other objects, features, advantages and technical and industrial significance of this disclosure will be better understood by reading the following detailed description of presently preferred embodiments of the disclosure, when considered in connection with the accompanying drawings.

### BRIEF DESCRIPTION OF THE DRAWINGS

FIG. 1 is an illustrative and schematic planar view of an optical waveguide structure according to a first embodiment;

FIG. 2 is an II-II cross-sectional view of FIG. 1;

FIG. 3 is a III-III cross-sectional view of FIG. 1;

FIG. 4 is an IV-IV cross-sectional view of FIG. 1;

FIG. 5 is a V-V cross-sectional view of FIG. 1;

FIG. 6 is an illustrative and schematic planar view of a part of an optical waveguide structure according to a modification example of the first embodiment;

FIG. 7 is an illustrative and schematic planar view of an optical waveguide structure according to a second embodiment;

FIG. 8 is a VIII-VIII cross-sectional view of FIG. 7;

FIG. 9 is an illustrative and schematic planar view of an optical waveguide structure according to a third embodiment;

FIG. 10 is an illustrative and schematic planar view of an optical waveguide structure according to a fourth embodiment;

FIG. 11 is an illustrative and schematic planar view of a semiconductor optical amplifier that includes an optical waveguide structure according to a fifth embodiment; and

FIG. 12 is an XII-XII cross-sectional view of FIG. 11.

### DETAILED DESCRIPTION

Exemplary embodiments are described below. The configurations explained in the embodiments described below as well as the actions and the results (effects) attributed to the configurations are only exemplary. Thus, the embodiments can be implemented also using some different configuration from the configurations disclosed in the embodiments described below. Meanwhile, according to the disclosure, it becomes possible to achieve at least one of various effects (including secondary effects) that are attributed to the configurations.

The embodiments and the modification examples described below include identical constituent elements. Thus, based on the identical configuration according to each embodiment and each modification example, it becomes possible to achieve identical actions and identical effects. In the following explanation, the identical constituent elements are referred to by the same reference numerals, and their explanation is not given in a repeated manner.

In the present written description, ordinal numbers are assigned only for convenience and with the aim of differentiating among the directions and the portions. Thus, the ordinal numbers neither indicate the priority or the sequencing nor restrict the count.

In the drawings, the X direction is indicated by an arrow X, the Y direction is indicated by an arrow Y, and the Z direction is indicated by an arrow Z. The X direction, the Y direction, and the Z direction intersect with each other and are orthogonal to each other. The X direction can be referred to as the direction of extension. The Y direction can be referred to as the width direction. The Z direction can be referred to as the height direction or the layering direction. Moreover, in the present written description, the planar view implies the view from the opposite direction to the Z direction.

Meanwhile, the drawings are schematic diagrams intended for use in the explanation. Thus, in the drawings, the scale and the ratio does not necessarily match with the actual objects.

### First Embodiment

### Basic Configuration

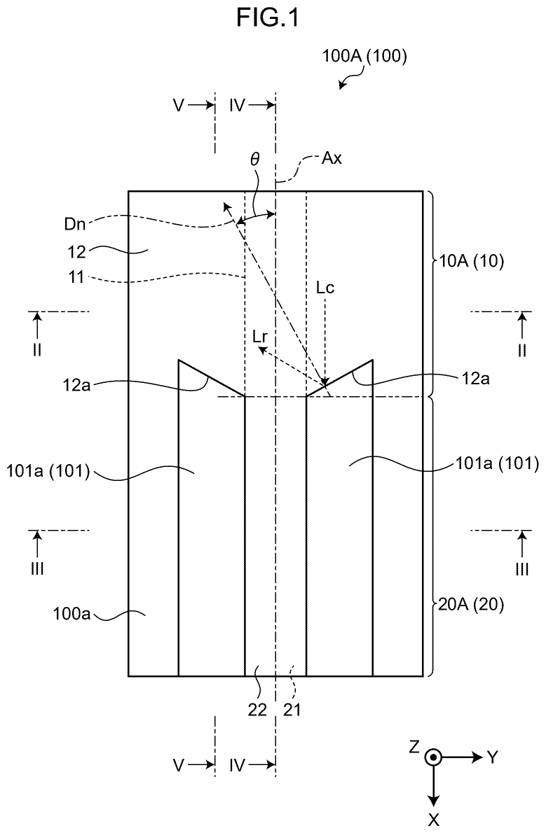

FIG. 1 is a planar view of an optical waveguide structure 100A (100) according to a first embodiment.

As illustrated in FIG. 1, the optical waveguide structure 100A (100) includes a first waveguide 10A (10) and a second waveguide 20A (20). The first waveguide 10 is a buried waveguide, and the second waveguide 20 is a high-mesa waveguide.

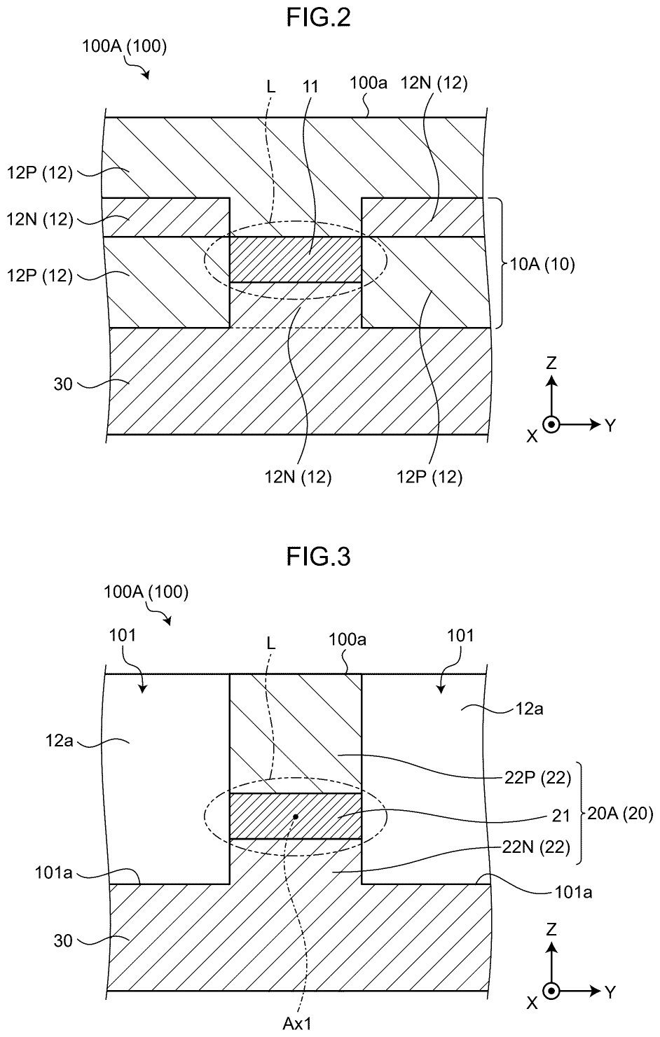

FIG. 2 is an II-II cross-sectional view of FIG. 1. As illustrated in FIG. 2, the first waveguide 10 has a layered structure in which each layer is layered on a substrate 30 in the Z direction. The substrate 30 is made of, for example, n-InP. The first waveguide 10 can be manufactured according to a known manufacturing method. The first waveguide 10 includes a core layer 11, and includes a cladding layer 12 that encloses the core layer 11. The core layer 11 is made of, for example, InGaAsP. The cladding layer 12 includes a p-cladding 12P and an n-cladding 12N. The p-cladding 12P is made of, for example, p-InP; and the n-cladding 12N is made of, for example, n-InP. Herein, the Z direction represents an example of a first direction. The core layer 11 represents an example of a first core layer. The cladding layer 12 represents an example of a first cladding layer.

Within the range illustrated in FIG. 1, that is, at least in the end portion of the first waveguide 10 in the X direction, the core layer 11 extends inside the cladding layer 12 and in the X direction with a substantially constant width in the Y direction and with a substantially constant height in the Z direction. The X direction represents an example of a second direction.

FIG. 3 is a III-III cross-sectional view of FIG. 1. As illustrated in FIG. 3, the second waveguide 20 also has a layered structure in which each layer is layered on the substrate 30 in the Z direction. The second waveguide 20 too can be manufactured according to a known manufacturing method. The second waveguide 20 includes a core layer 21, and includes a cladding layer 22 that sandwiches the core layer 21 in the Z direction. The core layer 21 is made of, for example, InGaAsP. The cladding layer 22 includes a p-cladding 22P and an n-cladding 22N. The p-cladding 22P is made of, for example, p-InP; and the n-cladding 22N is made of, for example, n-InP. Herein, the core layer 21 represents an example of a second core layer. The cladding layer 22 represents an example of a second cladding layer.

As illustrated in FIGS. 1 and 3, in the second waveguide 20, two depressed portions 101 that are depressed in the opposite direction to the Z direction from an end surface 100a in the Z direction are provided. Hence, with respect to a bottom surface 101a of each depressed portion 101, the second waveguide 20 is relatively protruding in the Z direction. In the first embodiment, the depressed portions 101 are hollow spaces, and it is possible to fill the depressed portions 101 with some kind of substance. In that case, the refractive index of the substance is different at least from the refractive index of the core layers 11 and 21, and is also different from the refractive index of the cladding layers 12 and 22. The depressed portions 101 represent examples of a hollow space, and also represent examples of an opening.

Within the range illustrated in FIG. 1, that is, at least in the end portion of the second waveguide 20 in the opposite direction to the X direction, the core layer 21 and the cladding layer 22 extend in the X direction with a substantially constant width in the Y direction is and with a substantially constant height in the Z direction.

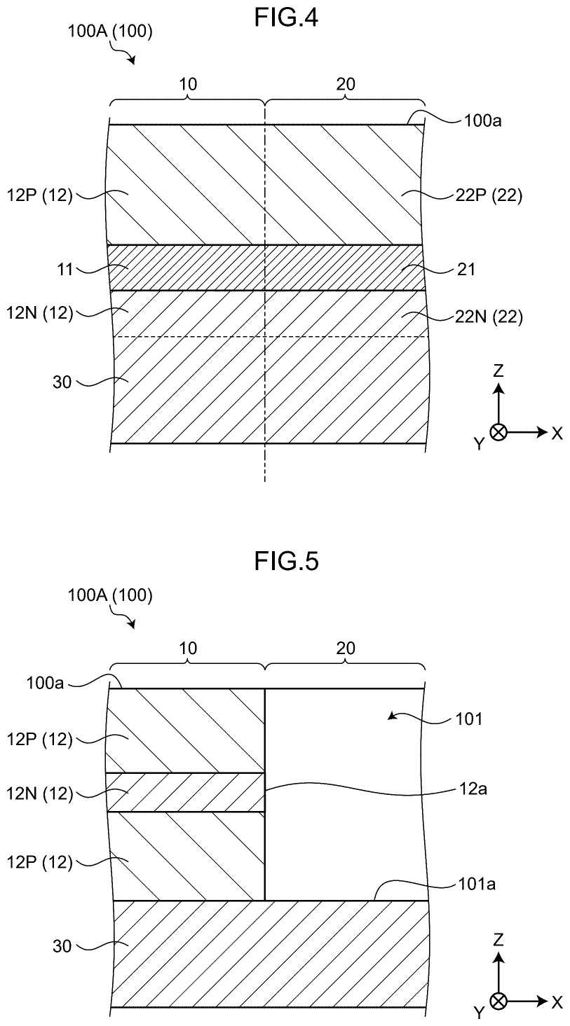

FIG. 4 is an IV-IV cross-sectional view of FIG. 1. As illustrated in FIG. 4, the n-cladding 22N of the second waveguide 20 is adjacent to the n-cladding 12N of the first waveguide 10 in the X direction. The core layer 21 of the second waveguide 20 is adjacent to the core layer 11 of the first waveguide 10 in the X direction. The p-cladding 22P of the second waveguide 20 is adjacent to the p-cladding 12P of the first waveguide 10 in the X direction. In the Z direction, the position of the core layer 11 is same as the position of the core layer 21, and the height of the core layer 11 is same as the height of the core layer 21. Moreover, as illustrated in FIG. 1, in the Y direction, the position of the core layer 11 is same as the position of the core layer 21, and the width of the core layer 11 is same as the width of the core layer 21. With such a configuration, the first waveguide 10 and the second waveguide 20 are optically connected to each other.

FIG. 5 is a V-V cross-sectional view of FIG. 1. As illustrated in FIGS. 5 and 3, an end surfaces 12a of the cladding layer 12 of the first waveguide 10 are present in the Y direction and the opposite direction to the Y direction with respect to the core layer 11, and face the corresponding depressed portions 101.

The region enclosed within the elliptical dashed line in FIG. 3 represents the transmission region of a light L. Generally, the light L that is transmitted in the first waveguide 10 having the abovementioned configuration is transmitted over a wider range than the core layer 11 as illustrated in FIG. 2. As an example, the outer edge of the light L can be defined as the position at which the intensity is equal to 1/e² of the maximum intensity of the central part of the light L. Meanwhile, the refractive index of the cladding layer 12 is different from the refractive index of the gaseous matter (for example, air) present inside the depressed portion 101. For that reason, of the light L transmitted in the first waveguide 10 in the X direction, the partial light that gets transmitted through the cladding layer 12 is reflected from the end surfaces 12a. That is, the end surfaces 12a constitute interfaces (first interfaces) having mutually different refractive indices. Of each end surface 12a, the portions that reflect the partial light of the light transmitted through the cladding layer 12 represent examples of a first reflecting surface.

In that case, if each end surface 12a extends in the Y direction in the planar view (see FIG. 1), sometimes the reflected light that is reflected from the end surface 12a travels through the cladding layer 12 in the opposite direction to the X direction, and gets recoupled with the cladding layer 12. Upon getting recoupled with the cladding layer 12, if the reflected light is input to a semiconductor optical amplifier which either includes the optical waveguide structure 100 or is optically connected to the optical waveguide structure, there is a risk of occurrence of an unfavorable phenomenon such as generation of ripples in the gain spectrum.

In that regard, in the first embodiment, as illustrated in FIG. 1, in the planar view, the end surfaces 12a are configured to be inclined with respect to the Y direction so that a partial light Lc of the light L that is transmitted through the cladding layer 12 gets reflected from each end surface 12a in a direction inclined with respect to the opposite direction to the X direction. In FIG. 1, Lr represents the reflected light of the partial light Lc of the light L that is transmitted through the cladding layer 12. According to the first embodiment, with such a configuration, it becomes possible to hold down a situation in which, of the light L that is transmitted through the cladding layer 12, the reflected light Lr of the partial light Lc gets recoupled with the first waveguide 10. In turn, it becomes possible to hold down the occurrence of an unfavorable phenomenon due to such recoupling.

The actions and the results (effects) attributed to the end surfaces 12a can be obtained also regarding the light that travels from the second waveguide 20 toward the first waveguide 10 in the opposite direction to the X direction.

Moreover, in such a configuration, it was found out that an angle θ representing an acute angle between a normal direction Dn of the region of each end surface 12a from which the partial light Lc, which is the part of the light L that is transmitted through the cladding layer 12, is reflected (i.e., the normal direction Dn of the first reflecting surface) and a central axis Ax of the core layers 11 and 21 desirably has the absolute value equal to or greater than 15° and equal to or smaller than 35°.

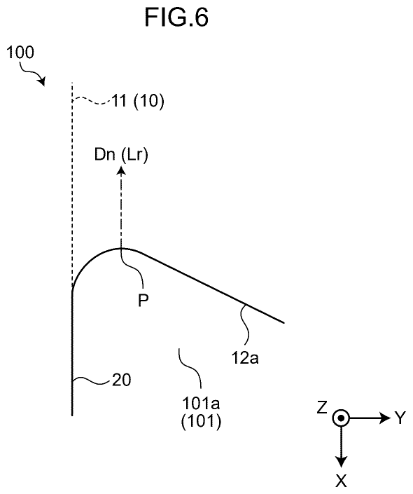

Furthermore, as illustrated in FIG. 1, in the first embodiment, the region of each end surface 12a from which the partial light Lc, which is the part of the light L that is transmitted through the cladding layer 12, is reflected (i.e., the normal direction Dn of the first reflecting surface) is desirably inclined in such a way that the end surface 12a moves closer to the central axis Ax of the core layers 11 and 21 as the inclination turns toward the X direction. The reason for having such a configuration is as follows. If the orientation is in the opposite direction, that is, as illustrated in a modification example in FIG. 6, if the first reflecting surface is inclined in such a way that the end surface 12a moves away from the central axis Ax as the inclination turns toward the X direction; in the vicinity of the connection with the second waveguide 20, there is a risk of occurrence of a portion P on the end surface 12a in which the normal direction Dn becomes oriented in the opposite direction to the X direction and the reflected light Lr travels in the opposite direction to the X direction.

As illustrated in FIG. 3, the region of each end surface 12a from which the partial light Lc, which is the portion of the light L that is transmitted through the cladding layer 12, is reflected (see FIG. 1), that is, the first reflecting surface is provided from the area on the side of an optical axis Ax1 with respect to the outer edge of the light L (the position of the dash-dot-dot line illustrated in FIG. 3) to the area on the opposite side to the optical axis Ax1 with respect to the outer edge of the light L. As a result, on the end surface 12a, the partial light Lc of the light L, which is transmitted through the cladding layer 12, can be reflected, with more reliability, in a direction in which there is no recoupling of the partial light Lc and the light L.

### Second Embodiment

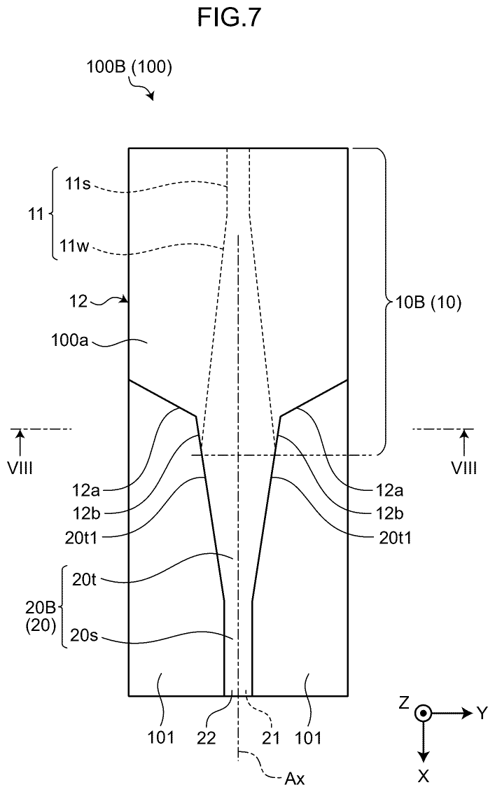

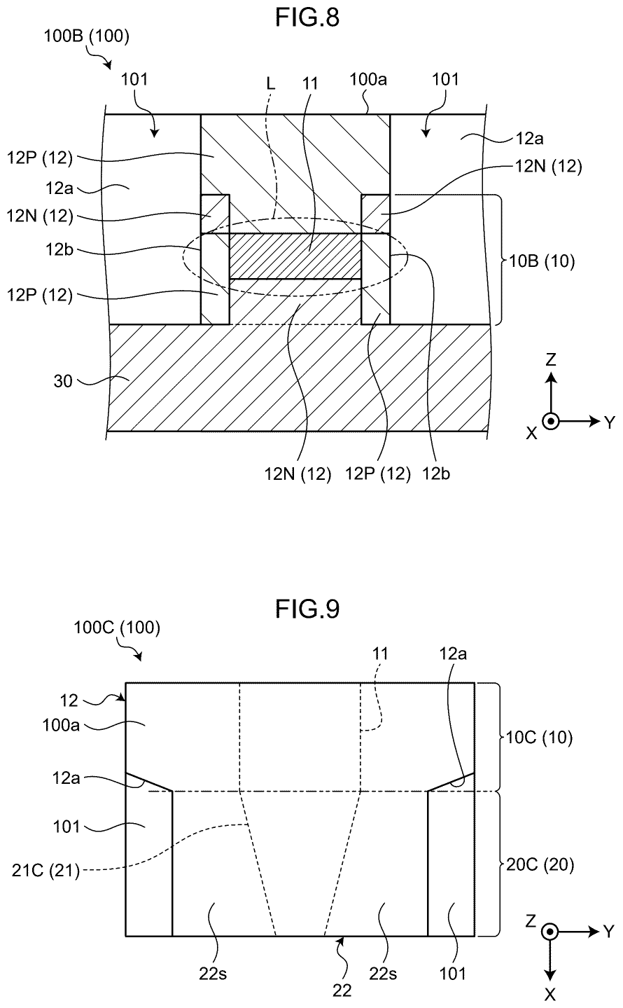

FIG. 7 is a planar view of an optical waveguide structure 100B (100) according to a second embodiment. FIG. 8 is a VIII-VIII cross-sectional view of FIG. 7. In the second embodiment too, in an identical manner to the first embodiment, the cladding layer 12 of a first waveguide 10B includes the end surfaces 12a. Hence, according to the second embodiment too, it becomes possible to achieve identical effects to the effects achieved according to the first embodiment.

However, in the second embodiment, as illustrated in FIG. 7, in the first waveguide 10B (10), the core layer 11 includes a linear portion 11s in which the width in the Y direction is substantially constant, and includes a widening portion 11w in which the width in the Y direction goes on gradually increasing toward the X direction. A second waveguide 20B (20) includes a tapering portion 20t in which the width in the Y direction goes on gradually decreasing toward the X direction, and includes a linear portion 20s in which the width in the Y direction is substantially constant. The tapering portion 20t constitutes a spot-size converter. Herein, the Y direction represents an example of a third direction.

Side surfaces 20t1 of the tapering portion 20t are inclined with respect to the X direction in such a way that the side surfaces 20t1 move closer to the central axis Ax of the core layer 21 or closer to the central axis Ax of the core layer 21 as the inclination turns toward the X direction. Each side surface 20t1 is the side surface of the tapering portion 20t either on the Y direction or on the opposite direction to the Y direction, and represents an example of a first side surface.

In the first waveguide 10B, the end part of the cladding layer 12 in the X direction includes side surfaces 12b present between the end surfaces 12a and the side surfaces 20t1. Each side surface 12b is adjacent to the corresponding side surface 20t1 of the tapering portion 20t in the opposite direction to the X direction, extends from the corresponding side surface 20t1 in a continuous manner, and is inclined with respect to the X direction. The side surfaces 12b represent examples of an extending portion.

In that case, in an identical manner to the first embodiment, the partial light of the light L that falls on the end surfaces 12a is reflected from the end surfaces 12a in a direction in which there is no recoupling of the partial light and the light L. Moreover, the partial light of the light L that falls on the inside part of the side surfaces 12b is confined to the inside part of the side surfaces 12b and gets coupled with the core layer 21.

In this way, the configuration in which the cladding layer 12 includes the end surfaces 12a can be applied also in the optical waveguide structure 100B that includes a spot-size converter in between the first waveguide 10 and the second waveguide 20.

### Third Embodiment

FIG. 9 is a planar view of an optical waveguide structure 100C (100) of a third embodiment. In the third embodiment too, in an identical manner to the first embodiment, the cladding layer 12 of a first waveguide 10C (10) includes the end surfaces 12a. Hence, according to the third embodiment too, it becomes possible to achieve identical effects to the effects achieved according to the first embodiment.

However, in the third embodiment, as illustrated in FIG. 9, a second waveguide 20C (20) is a double-cladding waveguide. That is, in the second waveguide 20C, the cladding layer 22 includes a portion that sandwiches the core layer 21 in the Z direction in an identical manner to the first embodiment, and includes portions 22s that sandwich a core layer 21C (21) in the Y direction and that enclose the core layer 21. The cladding layer 22 functions as the inside cladding of the double cladding. The depressed portions 101 are positioned on the opposite side of the core layer 21 with respect to the portions 22s, and function as the outside cladding of the double cladding.

Moreover, in the third embodiment, the width of the core layer 21C (21) in the Y direction goes on gradually decreasing toward the X direction, and constitutes a spot-size converter.

In this way, the configuration in which cladding layer 12 includes the end surfaces 12a can be applied also in the optical waveguide structure 100C in which the second waveguide 20C (20) is a double-cladding waveguide.

### Fourth Embodiment

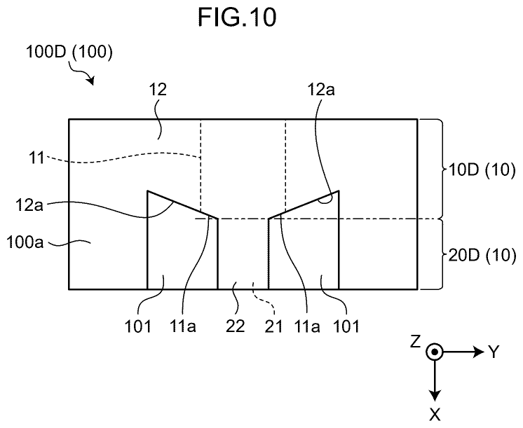

FIG. 10 is a planar view of an optical waveguide structure 100D (100) according to a fourth embodiment. In the fourth embodiment too, in an identical manner to the first embodiment, the cladding layer 12 of a first waveguide 10D (10) includes the end surfaces 12a. Hence, according to the fourth embodiment too, it becomes possible to achieve identical effects to the effects achieved according to the first embodiment.

However, in the fourth embodiment, as illustrated in FIG. 10, the width of the second waveguide 20D (20) in the Y direction is smaller than the width of the core layer 11 of the first waveguide 10D (10) in the Y direction, thereby resulting in a level difference between the core layers 11 and 21. In that level difference, the core layer 11 of the first waveguide 10D (10) includes end surfaces 11a that are continuous with the end surfaces 12a. The end surfaces 11a constitute interfaces between the core layer 11 and the medium filled inside the depressed portions 101. The medium represents the portions having a different refractive index from the refractive index of the core layer 11. The end surfaces 11a represent examples of a second interface.

In the planar view, in an identical manner to the end surfaces 12a, the end surfaces 11a are configured to be inclined with respect to the Y direction so that the partial light Lc of the light L that is transmitted through the cladding layer 12 gets reflected from the end surfaces 11a in a direction inclined with respect to the opposite direction to the X direction. According to the fourth embodiment, with such a configuration, it becomes possible to hold down a situation in which the reflected light from the end surfaces 11a gets recoupled with the first waveguide 10 thereby leading to a decline in the transmission characteristics of the light L. The end surfaces 11a represent examples of a second reflecting surface.

### Fifth Embodiment

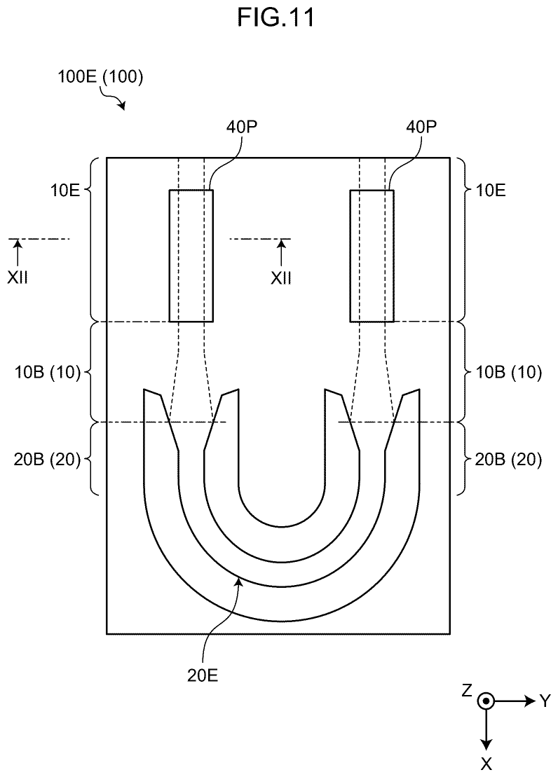

FIG. 11 is a planar view of an optical waveguide structure 100E (100) according to a fifth embodiment. In the fifth embodiment, two first waveguides 10B (10), which are identical to the second embodiment, are included; and two second waveguides 20B (20), which are identical to the second embodiment, are included and are optically connected to the first waveguides 10B (10). Hence, according to the fifth embodiment, it becomes possible to achieve identical effects to the effects achieved according to the second embodiment, and in turn it becomes possible to achieve identical effects to the effects achieved according to the first embodiment.

The optical waveguide structure 100E (100) is configured as a semiconductor optical amplifier. That is, in the fifth embodiment, the two second waveguides 20B are optically connected to each other via a U-shaped waveguide 20E. The waveguide 20E is a high-mesa waveguide having an identical cross-sectional structure to the cross-sectional structure of the second waveguides 20B, and represents a passive waveguide.

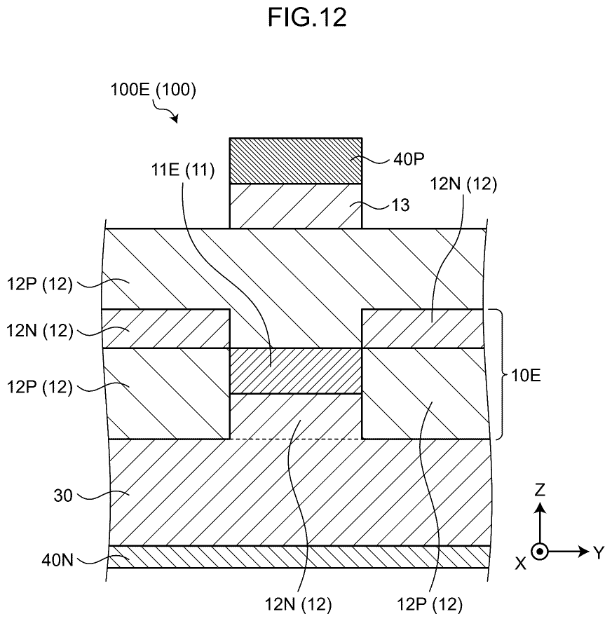

The optical waveguide structure 100E (100) includes waveguides 10E that are positioned on the opposite side of the second waveguides 20B (20) with respect to the first waveguides 10B (10) and that function as optical amplifying units. FIG. 12 is an XII-XII cross-sectional view of FIG. 11. As illustrated in FIG. 12, each waveguide 10E is a buried waveguide. A core layer 11E is an active layer and is made of, for example, InGaAsP. On the cladding layer 12P (12), a contact layer 13 is provided on the opposite side to the side of the core layer 11E. On each contact layer 13, an electrode 40P is disposed on the opposite side to the side of the core layer 11E. The contact layers 13 are made of P-type InGaAsP. The electrodes 40P are P-side electrodes and, for example, are configured with Au or AuZn. On the substrate 30, an electrode 40N is disposed on the opposite side to the side of the core layer 11E. The electrode 40N is an N-side electrode and, for example, is configured with AuGe, Ni, and Au.

In the waveguides 10E, as a result of passing an induced current among the electrodes 40P and 40N, it becomes possible to achieve the optical amplification action.

In this way, the configuration in which the cladding layer 12 includes the end surfaces 12a can be applied also in the optical waveguide structure 100E (100) that includes the waveguides 10E (10) functioning as optical amplifying units. In the fifth embodiment, the optical waveguide structure 100E functioning as a semiconductor optical amplifier includes the first waveguides 10B and the second waveguides 20B according to the second embodiment. However, that is not the only possible case. Thus, the optical waveguide structure 100E functioning as a semiconductor optical amplifier can include the first waveguides 10 according to any other embodiment or can include the second waveguides 20 according to any other embodiment.

While certain embodiments and modification examples have been described, these embodiments and modification examples have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Moreover, regarding the constituent elements, the specifications about the configurations and the shapes (structure, type, direction, shape, size, length, width, thickness, height, number, arrangement, position, material, etc.) can be suitably modified.

For example, the optical waveguide structure according to the embodiments can be applied also in some other type of optical device such as a wavelength-tunable laser.

According to the disclosure, it becomes possible to provide an optical waveguide structure and a semiconductor optical amplifier in a new and improved manner.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An optical waveguide structure comprising:
a first waveguide that
has a layered structure in which layering is performed in a first direction,
includes a first core layer that, at least in an end portion of the first waveguide in a second direction which intersects with the first direction, extends in the second direction, and
a first cladding layer that encloses the first core layer and that has an end surface in the second direction; and
a second waveguide that
has a layered structure in which layering is performed in the first direction,
includes a second core layer that is adjacent to the first core layer in the second direction, that is optically connected to the first core layer, and that, at least in an end portion of the second waveguide in an opposite direction to the second direction, extends in the second direction, and
a second cladding layer that sandwiches the second core layer in the first direction,
the optical waveguide structure transmitting a light in the second direction or in the opposite direction to the second direction, and
the end surface of the first cladding layer constituting a first interface between the first cladding layer and a portion having a different refractive index from a refractive index of the first cladding layer, wherein
the first interface includes a first reflecting surface configured to reflect a part of a transmitted light toward a direction inclined with respect to either the second direction or the opposite direction to the second direction to prevent the light reflected by the first reflecting surface from recoupling into the first waveguide or the second waveguide.

2. The optical waveguide structure according to claim 1, wherein the first reflecting surface is inclined with respect to either the second direction or the opposite direction to the second direction to approach a central axis of the first layer or the second layer toward the second direction.

3. The optical waveguide structure according to claim 1, wherein the first interface represents a boundary between the first cladding layer and a hollow space.

4. The optical waveguide structure according to claim 1, wherein the first interface represents a boundary between the first cladding layer and a substance that is filled in an opening provided in the optical waveguide structure.

5. The optical waveguide structure according to claim 1, wherein the second core layer includes an end part in the opposite direction to the second direction, the end part including a tapering portion having a width along a third direction that intersects with both of the first direction and the second direction, the width gradually decreasing toward the second direction.

6. The optical waveguide structure according to claim 5, wherein the end surface includes an extending portion that is positioned in between the first reflecting surface and the second core layer and that continuously extends from a first side surface positioned in the tapering portion in the third direction or in an opposite direction to the third direction.

7. The optical waveguide structure according to claim 1, wherein
the first core layer includes an end part in the second direction, the end part being continuous with the first interface and constituting a second interface between the first core layer and a portion having a different refractive index from a refractive index of the first core layer, and
the second interface includes a second reflecting surface configured to reflect a part of a transmitted light toward the direction inclined with respect to either the second direction or the opposite direction to the second direction to prevent the light reflected by the second reflecting surface from recoupling into the first waveguide or the second waveguide.

8. The optical waveguide structure according to claim 1, wherein the first reflecting surface is provided from an area on a side of an optical axis with respect to outer edge of a beam of light to be guided in the optical waveguide structure to an area on an opposite side to the optical axis with respect to the outer edge.

9. The optical waveguide structure according to claim 1, wherein the second waveguide is a high-mesa waveguide.

10. The optical waveguide structure according to claim 1, wherein the second waveguide is a double-cladding waveguide.

11. A semiconductor optical amplifier comprising the optical waveguide structure according to claim 1.
